(19) United States
(12) Patent Application Publication
(10) Pub. No.: US 2021/0165326 A1
(43) Pub. Date: Jun. 3, 2021

(54) POSITIVE-TYPE PHOTOSENSITIVE RESIN COMPOSITION AND CURED FILM PREPARED THEREFROM

(71) Applicant: ROHM AND HAAS ELECTRONIC MATERIALS KOREA LTD., Chungcheongnam-do (KR)

(72) Inventors: Kahee Shin, Gyeonggi-do (KR); Jung-Hwa LEE, Gyeonggi-do (KR); Jong-Ho NA, Gyeonggi-do (KR); Geun HUH, Gyeonggi-do (KR)

(21) Appl. No.: 17/089,602

(22) Filed: Nov. 4, 2020

(30) Foreign Application Priority Data
Dec. 2, 2019 (KR) 10-2019-0158041

(51) Int. Cl. G03F 7/075; G03F 7/022

(52) U.S. Cl. CPC G03F 7/0757; C08L 83/04; G03F 7/022

(57) ABSTRACT

The present invention relates to a positive-type photosensitive resin composition and a cured film prepared therefrom. The composition comprises a siloxane copolymer having specific structural units. Thus, a cured film formed from the composition may achieve a low edge angle of the pattern, thereby enhancing the resolution without deteriorating such physical properties as film retention rate and sensitivity.

### TECHNICAL FIELD

The present invention relates to a positive-type photosensitive resin composition capable of forming a cured film that is excellent in film retention rate and resolution, and a cured film prepared therefrom to be used for a pixel defining layer of an organic light emitting display device.

### BACKGROUND ART

In general, a positive-type photosensitive resin composition that requires fewer processing steps is widely employed in liquid crystal display devices, organic light emitting display devices, and the like.

However, a planarization film or a display element using a conventional positive-type photosensitive resin composition has slower sensitivity than a planarization film and a display element using a negative-type photosensitive resin composition. Therefore, the sensitivity of the former needs to be improved.

Meanwhile, conventional positive photosensitive resin compositions generally comprise an alkali-soluble resin such as a siloxane polymer and an acrylic polymer as a binder resin, along with a photosensitive agent such as a quinonediazide-based compound, an aromatic aldehyde, or the like (see Japanese Laid-open Patent Publication No. 1996-234421).

However, when a cured film is formed using such a positive-type photosensitive resin composition, the rate of loss in the thickness of the cured film by a developer during the developing step is large, and there is a limit to achieving sufficiently satisfying film retention rate, resolution, and the like.

Meanwhile, the interlayer insulation layer or the pixel defining layer of an organic light emitting display device must have a relatively low edge angle of the hole pattern. If the edge angle of the hole pattern is too high, cracks or short circuits may occur in the metal layer formed on the pattern, so that excessive electrical resistance may be applied to the pattern edge when the device is driven.

### DETAILED DESCRIPTION OF THE INVENTION

### Technical Problem

Accordingly, the present invention aims to provide a positive-type photosensitive resin composition capable of forming a cured film that is excellent in film retention rate and resolution while maintaining a low edge angle of the pattern, and a cured film prepared therefrom to be used for a pixel defining layer or an interlayer insulation layer of an organic light emitting display device.

### Solution to the Problem

In order to accomplish the above object, the present invention provides a positive-type photosensitive resin composition, which comprises (A) a siloxane copolymer comprising a structural unit represented by the following Formula 1 and a structural unit represented by the following Formula 2; and (B) a photoactive compound; and (C) a solvent.

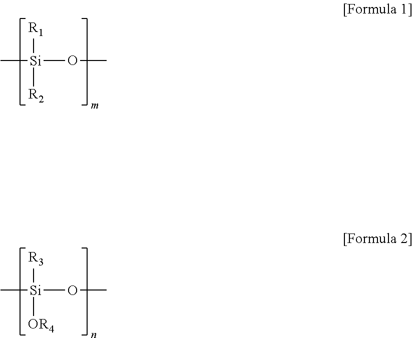

In Formulae 1 and 2, R₁, R₂, and R₃ are each independently C₁₋₁₂ alkyl, C₂₋₁₀ alkenyl, C₆₋₁₅ aryl, 3- to 12-membered heteroalkyl, 4- to 10-membered heteroalkenyl, or 6- to 15-membered heteroaryl, at least one of R₁, R₂, and R₃ is C₆₋₁₅ aryl, and the heteroalkyl, the heteroalkenyl, and the heteroaryl groups each independently contain at least one identical or different heteroatom selected from the group consisting of N, O and S; R₄ is each independently hydrogen, C₁₋₆ alkyl, C₂₋₆ acyl, or C₆₋₁₅ aryl; and m and n are the molar fractions of the structural units, which satisfy 0.25≤m≤0.63, 0.37≤n≤0.75, and m+n=1.

In order to achieve another object, the present invention provides a cured film prepared from the photosensitive resin composition.

### Advantageous Effects of the Invention

The positive-type photosensitive resin composition according to the present invention comprises a siloxane copolymer having specific structural units. Thus, a cured film formed from the composition may achieve a low edge angle of the pattern, thereby enhancing the resolution without deteriorating such physical properties as film retention rate and sensitivity.

### BRIEF DESCRIPTION OF THE DRAWINGS

FIG. 1 shows each photograph of a transversal cross-section of a 10 μm-hole in a pattern formed on the surface of a cured film obtained in Examples 1 to 6 and Comparative Examples 1 to 3 by a scanning electron microscope.

### BEST MODE FOR CARRYING OUT THE INVENTION

The present invention is not limited to those described below. Rather, it can be modified into various forms as long as the gist of the invention is not altered.

Throughout the present specification, when a part is referred to as “comprising” an element, it is understood that other elements may be comprised, rather than other elements are excluded, unless specifically stated otherwise. In addition, all numbers and expressions relating to quantities of components, reaction conditions, and the like used herein are to be understood as being modified by the term “about” unless specifically stated otherwise.

The present invention provides a photosensitive resin composition, which comprises (A) a siloxane copolymer comprising specific structural units; (B) a photoactive compound; and (C) a solvent. In addition, the composition may optionally further comprise (D) an epoxy compound; (E) a siloxane binder; (F) a photopolymerizable compound containing a double bond; (G) a surfactant; and/or (H) a silane compound.

As used herein, the term “(meth)acryl” refers to “acryl” and/or “methacryl,” and the term “(meth)acrylate” refers to “acrylate” and/or “methacrylate.”

The weight average molecular weight (g/mole or Da) of each component as described below is measured by gel permeation chromatography (GPC, eluent: tetrahydrofuran) referenced to a polystyrene standard.

(A) Siloxane Copolymer

The photosensitive resin composition of the present invention comprises a siloxane copolymer (A) comprising a structural unit represented by the following Formula 1 and a structural unit represented by the following Formula 2.

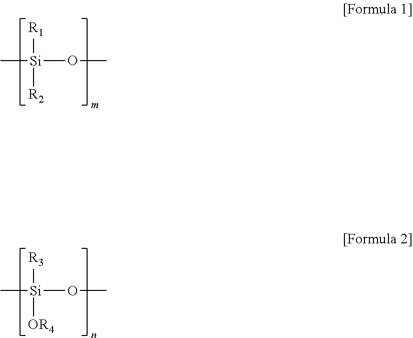

In the above formulae, R₁, R₂, and R₃ are each independently C₁₋₁₂ alkyl, C₂₋₁₀ alkenyl, C₆₋₁₅ aryl, 3- to 12-membered heteroalkyl, 4- to 10-membered heteroalkenyl, or 6- to 15-membered heteroaryl, at least one of R₁, R₂, and R₃ is C₆₋₁₅ aryl, and the heteroalkyl, the heteroalkenyl, and the heteroaryl groups each independently contain at least one identical or different heteroatom selected from the group consisting of N, O and S; R₄ is each independently hydrogen, C₁₋₆ alkyl, C₂₋₆ acyl, or C₆₋₁₅ aryl; and m and n are mole fractions of the structural units, which satisfy 0.25≤m≤0.63, 0.37≤n≤0.75, and m+n=1.

The siloxane copolymer comprising the structural units represented by the above Formulae 1 and 2 reduces the degree of crosslinking in the composition when a cured film is prepared, thereby appropriately increasing the flowability at the time of hard-bake. Thus, the edge angle of the pattern can be lowered.

The siloxane copolymer may comprise a phenyl group and comprise the phenyl group at a molar ratio of 1 to 1.5, 1 to 1.3, or 1 to 1.2, per 1 mole of Si atom.

The molar ratio can be calculated by measuring the molar amount of the siloxane copolymer by the combination of Si-NMR, ¹H-NMR, ¹³C-NMR, IR, TOF-MS, elementary analysis, measurement of ash, and the like. For example, an Si-NMR analysis is performed on the entire siloxane copolymer, followed by an analysis of the phenyl-bound Si peak area and the phenyl-unbound Si peak area. The molar ratio between them can then be computed.

The weight average molecular weight of the siloxane copolymer may be 500 to 2,000 Da, 500 to 1,800 Da, 500 to 1,500 Da, or 800 to 1,500 Da. In addition, the acid value of the siloxane copolymer may be 5 to 20 mg KOH/g or 5 to 15 mg KOH/g.

The photosensitive resin composition of the present invention may comprise the siloxane polymer in an amount of 0.1 to 10% by weight, 0.1 to 8% by weight, 0.1 to 5% by weight, 1 to 10% by weight, 1 to 8% by weight, or 1 to 5% by weight, based on the total weight of the composition on the basis of the solids content, exclusive of solvents. Within the above range, excellent resolution can be obtained while a low edge angle of the pattern is maintained. Outside the above range, for example, the edge angle of the pattern may be higher, or the sensitivity may be deteriorated due to insufficient developability.

(B) Photoactive Compound

The photosensitive resin composition according to the present invention may comprise a 1,2-quinonediazide-based compound as a photoactive compound. The photoactive compound serves to initiate the polymerization of monomers that can be cured by visible light, ultraviolet radiation, deep-ultraviolet radiation, or the like.

The 1,2-quinonediazide-based compound is not particularly limited as long as it is used as a photosensitive agent in the photoresist field and has a 1,2-quinonediazide-based structure.

Examples of the 1,2-quinonediazide-based compound include an ester compound of a phenolic compound and 1,2-benzoquinonediazide-4-sulfonic acid or 1,2-benzoquinonediazide-5-sulfonic acid; an ester compound of a phenolic compound and 1,2-naphthoquinonediazide-4-sulfonic acid or 1,2-naphthoquinonediazide-5-sulfonic acid; a sulfonamide compound of a phenolic compound in which the hydroxyl group is substituted with an amino group and 1,2-benzoquinonediazide-4-sulfonic acid or 1,2-benzoquinonediazide-5-sulfonic acid; a sulfonamide compound of a phenolic compound in which the hydroxyl group is substituted with an amino group and 1,2-naphthoquinonediazide-4-sulfonic acid or 1,2-naphthoquinonediazide-5-sulfonic acid. The above compounds may be used alone or in combination of two or more thereof.

Examples of the phenolic compound include 2,3,4-trihydroxybenzophenone, 2,4,6-trihydroxybenzophenone, 2,2′,4,4′-tetrahydroxvbenzophenone, 2,3,3′,4-tetrahydroxybenzophenone, 2,3,4,4′-tetrahydroxybenzophenone, bis(2,4-dihydroxyphenyl)methane, bis(p-hydroxyphenyl)methane, tri(p-hydroxyphenyl)methane, 1,1,1-tri(p-hydroxyphenyl)ethane, bis(2,3,4-trihydroxyphenyl)methane, 2,2-bis(2,3,4-trihydroxyphenyl)propane, 1,1,3-tris(2,5-dimethyl-4-hydroxyphenyl)-3-phenylpropane, 4,4′-[1-[4-[1-[4-hydroxyphenyl]-1-methylethyl]phenyl]ethylidene]bisphenol, bis(2,5-dimethyl-4-hydroxyphenyl)-2-hydroxyphenylmethane, 3,3,3′,3′-tetramethyl-1,1′-spirobiindene-5,6,7,5′,6′,7′-hexanol, 2,2,4-trimethyl-7,2′,4′-trihydroxyflavane, bis[4-hydroxy-3-(2-hydroxy-5-methylbenzyl)-5-dimethylphenyl]methane, and the like.

Particular examples of the 1,2-quinonediazide-based compound include an ester compound of 2,3,4-trihydroxybenzophenone and 1,2-naphthoquinonediazide-4-sulfonic acid, an ester compound of 2,3,4-trihydroxybenzophenone and 1,2-naphthoquinonediazide-5-sulfonic acid, an ester compound of 4,4′-[1-[4-[1-[4-hydroxyphenyl]-1-methylethyl]phenyl]ethylidene]bisphenol and 1,2-naphthoquinonediazide-4-sulfonic acid, an ester compound of 4,4′-[1-[4-[1-[4-hydroxyphenyl]-1-methylethyl]phenyl]ethylidene]bisphenol and 1,2-naphthoquinonediazide-5-sulfonic acid, an ester compound of bis[4-hydroxy-3-(2-hydroxy-5-methylbenzyl)-5-dimethylphenyl]methane and 1,2-naphthoquinonediazide-5-sulfonic acid, and the like. More particular examples include at least one selected from the group consisting of 1,2-quinonediazide 4-sulfonic acid ester, 1,2-quinonediazide 5-sulfonic acid ester, and 1,2-quinonediazide 6-sulfonic acid ester. If the compounds exemplified above are used as the 1,2-quinonediazide-based compound, the transparency of the photosensitive resin composition may be further enhanced.

The 1,2-quinonediazide-based compound may be employed in an amount ranging from 2 to 50 parts by weight or 5 to 20 parts by weight based on 100 parts by weight of the siloxane binder (E) on the basis of the solids content. Within the above content range, a pattern is more readily formed from the resin composition, and it is possible to suppress such defects as a rough surface of a coated film upon the formation thereof and such a pattern shape as scum appearing at the bottom portion of the pattern upon development.

(C) Solvent

The photosensitive resin composition of the present invention may be prepared as a liquid composition in which the above components are mixed with a solvent. The solvent may be, for example, an organic solvent.

The amount of the solvent in the photosensitive resin composition according to the present invention is not particularly limited. For example, the solvent may be employed such that the solids content is 10 to 90% by weight, 10 to 85% by weight, 10 to 70% by weight, 15 to 60% by weight, 30 to 90% by weight, or 40 to 85% by weight, based on the total weight of the photosensitive resin composition. The solids content refers to the components constituting the resin composition of the present invention, exclusive of solvents. If the amount of the solvent is within the above range, the coating of the composition can be readily carried out, while the flowability thereof can be maintained at a proper level.

The solvent is not particularly limited as long as it can dissolve the above-mentioned components and is chemically stable. For example, the solvent may be an alcohol, an ether, a glycol ether, an ethylene glycol alkyl ether acetate, diethylene glycol, a propylene glycol monoalkyl ether, a propylene glycol alkyl ether acetate, a propylene glycol alkyl ether propionate, an aromatic hydrocarbon, a ketone, an ester, and the like.

Specifically, examples of the solvent include methanol, ethanol, tetrahydrofuran, dioxane, methyl cellosolve acetate, ethyl cellosolve acetate, ethyl acetoacetate, ethylene glycol monomethyl ether, ethylene glycol monoethyl ether, ethylene glycol dimethyl ether, ethylene glycol diethyl ether, propylene glycol dimethyl ether, propylene glycol diethyl ether, diethylene glycol monomethyl ether, diethylene glycol monoethyl ether, diethylene glycol dimethyl ether, diethylene glycol ethyl methyl ether, propylene glycol monomethyl ether, propylene glycol monoethyl ether, propylene glycol monopropyl ether, dipropylene glycol dimethyl ether, dipropylene glycol diethyl ether, propylene glycol methyl ether acetate, propylene glycol ethyl ether acetate, propylene glycol propyl ether acetate, dipropylene glycol methyl ether acetate, propylene glycol butyl ether acetate, toluene, xylene, methyl ethyl ketone, 4-hydroxy-4-methyl-2-pentanone, cyclopentanone, cyclohexanone, 2-heptanone, γ-butyrolactone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 2-methoxypropionate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, N,N-dimethylformamide, N,N-dimethylacetamide, N-methylpyrrolidone, and the like.

Preferred among the above are ethylene glycol alkyl ether acetates, diethylene glycols, propylene glycol monoalkyl ethers, propylene glycol alkyl ether acetates, ketones, and the like. Particularly preferred are diethylene glycol dimethyl ether, diethylene glycol ethyl methyl ether, dipropylene glycol dimethyl ether, dipropylene glycol diethyl ether, propylene glycol monomethyl ether, propylene glycol monoethyl ether, propylene glycol methyl ether acetate, methyl 2-methoxypropionate, γ-butyrolactone, 4-hydroxy-4-methyl-2-pentanone, and the like. The solvents exemplified above may be used alone or in combination of two or more thereof.

(D) Epoxy Compound

The photosensitive resin composition according to the present invention may comprise an epoxy compound.

The epoxy compound serves to increase the internal density of the siloxane copolymer (A) and/or the siloxane binder (E). Thus, it is possible to improve the chemical resistance of a cured film to be prepared therefrom comprising them.

The epoxy compound may be a homo-oligomer or a hetero-oligomer of an unsaturated monomer containing at least one epoxy group.

Examples of the unsaturated monomer containing at least one epoxy group may include glycidyl (meth)acrylate, 4-hydroxybutylacrylate glycidyl ether, 3,4-epoxybutyl (meth)acrylate, 4,5-epoxypentyl (meth)acrylate, 5,6-epoxyhexyl (meth)acrylate, 6,7-epoxyheptyl (meth)acrylate, 2,3-epoxycyclopentyl (meth)acrylate, 3,4-epoxycyclohexyl (meth)acrylate, α-ethyl glycidyl acrylate, α-n-propyl glycidyl acrylate, α-n-butyl glycidyl acrylate, N-(4-(2,3-epoxypropoxy)-3,5-dimethylbenzyl)acrylamide, N-(4-(2,3-epoxypropoxy)-3,5-dimethylphenylpropyl)acrylamide, allyl glycidyl ether, 2-methylallyl glycidyl ether, o-vinylbenzyl glycidyl ether, m-vinylbenzyl glycidyl ether, p-vinylbenzyl glycidyl ether, and a mixture thereof.

The epoxy compound may be synthesized by any methods well known in the art.

Examples of the commercially available epoxy compound may be GHP24HP or GHP03HP.

The epoxy compound may further comprise the following structural unit.

Particular examples thereof may include any structural unit derived from styrene; a styrene having an alkyl substituent such as methylstyrene, dimethylstyrene, trimethylstyrene, ethylstyrene, diethylstyrene, triethylstyrene, propylstyrene, butylstyrene, hexylstyrene, heptylstyrene, and octylstyrene; a styrene having a halogen such as fluorostyrene, chlorostyrene, bromostyrene, and iodostyrene; a styrene having an alkoxy substituent such as methoxystyrene, ethoxystyrene, and propoxystyrene; p-hydroxy-α-methylstyrene, acetylstyrene; an ethylenically unsaturated compound having an aromatic ring such as divinylbenzene, vinylphenol, o-vinylbenzyl methyl ether, m-vinylbenzyl methyl ether, and p-vinylbenzyl methyl ether; an unsaturated carboxylic acid ester such as methyl (meth)acrylate, ethyl (meth)acrylate, butyl (meth)acrylate, dimethylaminoethyl (meth)acrylate, isobutyl (meth)acrylate, t-butyl (meth)acrylate, cyclohexyl (meth)acrylate, ethylhexyl (meth)acrylate, tetrahydrofurfuryl (meth)acrylate, hydroxyethyl (meth)acrylate, 2-hydroxypropyl (meth)acrylate, 2-hydroxy-3-chloropropyl (meth)acrylate, 4-hydroxybutyl (meth)acrylate, glycerol (meth)acrylate, methyl α-hydroxymethylacrylate, ethyl α-hydroxymethylacrylate, propyl α-hydroxymethylacrylate, butyl α-hydroxymethylacrylate, 2-methoxyethyl (meth)acrylate, 3-methoxybutyl (meth)acrylate, ethoxy diethylene glycol (meth)acrylate, methoxy triethylene glycol (meth)acrylate, methoxy tripropylene glycol (meth)acrylate, poly(ethylene glycol) methyl ether (meth)acrylate, phenyl (meth)acrylate, benzyl (meth)acrylate, 2-phenoxyethyl (meth)acrylate, phenoxy diethylene glycol (meth)acrylate, p-nonylphenoxy polyethylene glycol (meth)acrylate, p-nonylphenoxy polypropylene glycol (meth)acrylate, tetrafluoropropyl (meth)acrylate, 1,1,1,3,3,3-hexafluoroisopropyl (meth)acrylate, octafluoropentyl (meth)acrylate, heptadecafluorodecyl (meth)acrylate, tribromophenyl (meth)acrylate, isobornyl (meth)acrylate, dicyclopentanyl (meth)acrylate, dicyclopentenyl (meth)acrylate, dicyclopentanyloxyethyl (meth)acrylate, and dicyclopentenyloxyethyl (meth)acrylate; a tertiary amine having an N-vinyl group such as N-vinyl pyrrolidone, N-vinyl carbazole, and N-vinyl morpholine; an unsaturated ether such as vinyl methyl ether and vinyl ethyl ether; an unsaturated imide such as N-phenylmaleimide, N-(4-chlorophenyl)maleimide, N-(4-hydroxyphenyl)maleimide, and N-cyclohexylmaleimide. The structural unit derived from the compounds exemplified above may be contained in the epoxy compound alone or in combination of two or more thereof. The styrene-based compounds among the above compounds may be further preferable in consideration of polymerizability.

In such event, the epoxy compound does not contain a structural unit derived from a monomer having a carboxyl group. That is, it is more preferable in terms of the chemical resistance that the epoxy compound does not contain a carboxyl group.

The structural unit may be employed in an amount of 0 to 70% by mole or 10 to 60% by mole, based on the total number of moles of the structural units constituting the epoxy compound. Within the above content range, it may be more advantageous in terms of the film strength.

The weight average molecular weight of the epoxy compound may be 100 to 30,000 Da or 1,000 to 15,000 Da. If the weight average molecular weight of the epoxy compound is at least 100 Da, the hardness of a cured film may be more favorable. If it is 30,000 Da or less, a cured film may have a uniform thickness, which is suitable for planarizing any steps thereon.

The photosensitive resin composition of the present invention may comprise the epoxy compound in an amount of 1 to 40% by weight or 5 to 25% by weight, based on the total weight of the solids content of the composition, exclusive of solvents.

Within the above content range, the film strength and the sensitivity are excellent. Outside the above range, for example, the film strength and the chemical resistance are significantly deteriorated when used in a small amount less than the above content, and the sensitivity may be deteriorated when used in an excessive amount.

(E) Siloxane Binder

The photosensitive resin composition of the present invention comprises a siloxane binder, as described below, as an alkali-soluble resin, whereby it is possible to form a positive pattern by a process ranging from exposure to development. If a resin other than a siloxane binder, such as an acrylate-based resin, is used as an alkali-soluble resin, there is a disadvantage in that the film retention rate is significantly deteriorated, and reliability may be deteriorated due to insufficient thermal resistance and light resistance.

The siloxane binder may include a silane compound and/or a condensate of a hydrolysate thereof. In such event, the silane compound or the hydrolysate thereof may be a monofunctional to tetrafunctional silane compound. As a result, the siloxane polymer may comprise a siloxane structural unit selected from the following Q, T, D, and M types:
Q type siloxane structural unit: a siloxane structural unit comprising a silicon atom and adjacent four oxygen atoms, which may be derived from, e.g., a tetrafunctional silane compound or a hydrolysate of a silane compound that has four hydrolyzable groups.
T type siloxane structural unit: a siloxane structural unit comprising a silicon atom and adjacent three oxygen atoms, which may be derived from, e.g., a trifunctional silane compound or a hydrolysate of a silane compound that has three hydrolyzable groups.
D type siloxane structural unit: a siloxane structural unit comprising a silicon atom and adjacent two oxygen atoms (i.e., a linear siloxane structural unit), which may be derived from, e.g., a difunctional silane compound or a hydrolysate of a silane compound that has two hydrolyzable groups.
M type siloxane structural unit: a siloxane structural unit comprising a silicon atom and one adjacent oxygen atom, which may be derived from, e.g., a monofunctional silane compound or a hydrolysate of a silane compound that has one hydrolyzable group.

Specifically, the siloxane binder may comprise a structural unit derived from a silane compound represented by the following Formula 3:

(R₅)ₚSi(OR₆)₄₋ₚ [Formula 3]

In Formula 3, R₅ is each independently C₁₋₁₂ alkyl, C₂₋₁₀ alkenyl, C₆₋₁₅ aryl, 3- to 12-membered heteroalkyl, 4- to 10-membered heteroalkenyl, or 6- to 15-membered heteroaryl, and the heteroalkyl, the heteroalkenyl, and the heteroaryl groups each independently contain at least one identical or different heteroatom selected from the group consisting of N, O and S; R₆ is each independently hydrogen, C₁₋₅ alkyl, C₂₋₆ acyl, or C₆₋₁₅ aryl; and p is an integer of 0 to 3.

In such event, it may be a tetrafunctional silane compound where p is 0, a trifunctional silane compound where p is 1, a difunctional silane compound where p is 2, or a monofunctional silane compound where p is 3.

Particular examples of the silane compound may include, e.g., as the tetrafunctional silane compound, tetraacetoxysilane, tetramethoxysilane, tetraethoxysilane, tetrabutoxysilane, tetraphenoxysilane, tetrabenzyloxysilane, and tetrapropoxysilane; as the trifunctional silane compound, methyltrimethoxysilane, methyltriethoxysilane, methyltriisopropoxysilane, methyltributoxysilane, ethyltrimethoxysilane, ethyltriethoxysilane, ethyltriisopropoxysilane, ethyltributoxysilane, butyltrimethoxysilane, pentafluorophenyltrimethoxysilane, phenyltrimethoxysilane, phenyltriethoxysilane, d³-methyltrimethoxysilane, nonafluorobutylethyltrimethoxysilane, trifluoromethyltrimethoxysilane, n-propyltrimethoxysilane, n-propyltriethoxysilane, n-butyltriethoxysilane, n-hexyltrimethoxysilane, n-hexyltriethoxysilane, decyltrimethoxysilane, vinyltrimethoxysilane, vinyltriethoxysilane, 3-methacryloxypropyltrimethoxysilane, 3-methacryloxypropyltriethoxysilane, 3-acryloxypropyltrimethoxysilane, 3-acryloxypropyltriethoxysilane, p-hydroxyphenyltrimethoxysilane, 1-(p-hydroxyphenyl)ethyltrimethoxysilane, 2-(p-hydroxyphenyl)ethyltrimethoxysilane, 4-hydroxy-5-(p-hydroxyphenylcarbonyloxy)pentyltrimethoxysilane, trifluoromethyltriethoxysilane, 3,3,3-trifluoropropyltrimethoxysilane, 3-aminopropyltrimethoxysilane, 3-aminopropyltriethoxysilane, 3-glycidoxypropyltrimethoxysilane, 3-glycidoxypropyltriethoxysilane, 2-(3,4-epoxycyclohexyl)ethyltrimethoxysilane, 2-(3,4-epoxycyclohexyl)ethyltriethoxysilane, [(3-ethyl-3-oxetanyl)methoxy]propyltrimethoxysilane, [(3-ethyl-3-oxetanyl)methoxy]propyltriethoxysilane, 3-mercaptopropyltrimethoxysilane, and 3-trimethoxysilylpropylsuccinic acid; as the difunctional silane compound, dimethyldiacetoxysilane, dimethyldimethoxysilane, diphenyldimethoxysilane, diphenyldiethoxysilane, diphenyldiphenoxysilane, dibutyldimethoxysilane, dimethyldiethoxysilane, (3-glycidoxypropyl)methyldimethoxysilane, (3-glycidoxypropyl)methyldiethoxysilane, 3-(2-aminoethylamino)propyldimethoxymethylsilane, 3-aminopropyldiethoxymethylsilane, 3-chloropropyldimethoxymethylsilane, 3-mercaptopropyldimethoxymethylsilane, cyclohexyldimethoxymethylsilane, diethoxymethylvinylsilane, dimethoxymethylvinylsilane, and dimethoxydi-p-tolylsilane; and as the monofunctional silane compound, trimethylmethoxysilane, tributylmethoxysilane, trimethylethoxysilane, (3-glycidoxypropyl)dimethylmethoxysilane, and (3-glycidoxypropyl)dimethylethoxysilane.

Preferred among the tetrafunctional silane compounds are tetramethoxysilane, tetraethoxysilane, and tetrabutoxysilane; preferred among the trifunctional silane compoundsaremethyltrimethoxysilane, methyltriethoxysilane, methyltriisopropoxysilane, methyltributoxysilane, phenyltrimethoxysilane, ethyltrimethoxysilane, ethyltriethoxysilane, ethyltriisopropoxysilane, ethyltributoxysilane, butyltrimethoxysilane, 3-glycidoxypropyltrimethoxysilane, 3-glycidoxypropyltriethoxysilane, 2-(3,4-epoxycyclohexyl)ethyltrimethoxysilane, and 2-(3,4-epoxycyclohexyl)ethyltriethoxysilane; preferred among the difunctional silane compounds are dimethyldimethoxysilane, diphenyldimethoxysilane, diphenyldiethoxysilane, diphenyldiphenoxysilane, dibutyldimethoxysilane, and dimethyldiethoxysilane.

The conditions for obtaining a hydrolysate or a condensate of the silane compound of the above Formula 3 are not particularly limited.

The weight average molecular weight of the condensate (i.e., siloxane binder) obtained by the hydrolytic polymerization of the silane compound of the above Formula 3 may be 500 to 50,000 Da, 1,000 to 50,000 Da, 3,000 to 30,000 Da, or 5,000 to 20,000 Da. Within the above range, it is more preferable in terms of the film formation characteristics, solubility, dissolution rate to a developer, and the like.

The siloxane binder may comprise a structural unit derived from a silane compound represented by the above Formula 3 where p is 0 (i.e., Q-type structural unit). Specifically, the siloxane polymer may comprise the structural unit derived from the silane compound represented by the above Formula 3 where p is 0 in an amount of 10 to 50% by mole or 15 to 40% by mole based on an Si atomic mole number.

If the amount of the Q-type structural unit is within the above content range, the photosensitive resin composition may maintain its solubility to an aqueous alkaline solution at a proper level during the formation of a pattern, thereby preventing any defects caused by a reduction in the solubility or a drastic increase in the solubility of the composition.

The siloxane binder may comprise a structural unit derived from a silane compound represented by the above Formula 3 where p is 1 (i.e., T-type structural unit). For example, the siloxane polymer may comprise the structural unit derived from the silane compound of the above Formula 3 where p is 1 in an amount ratio of 40 to 99% by mole or 50 to 95% by mole based on an Si atomic mole number. If the amount of the T-type structural unit is within the above content range, it is more preferable to form a more precise pattern profile.

In addition, it is more preferable that the siloxane binder comprises a structural unit derived from a silane compound having an aryl group in terms of the hardness, sensitivity, and retention rate of a cured film. For example, the siloxane polymer may comprise a structural unit derived from a silane compound having an aryl group in an amount of 20 to 80% by mole, 30 to 70% by mole, or 30 to 50% by mole, based on an Si atomic mole number. If the amount of the structural unit derived from a silane compound having an aryl group is within the above content range, the compatibility of the siloxane binder with the photoactive compound (or 1,2-quinonediazide-based compound) is excellent, which may prevent an excessive decrease in sensitivity while attaining more favorable transparency of a cured film.

The structural unit derived from the silane compound having an aryl group may be, for example, a structural unit derived from a silane compound of the above Formula 3 where R₅ is an aryl group, specifically a silane compound of the above Formula 3 where p is 1 and R₅ is an aryl group, more specifically a silane compound of the above Formula 3 where p is 1 and R₅ is a phenyl group (i.e., siloxane structural unit of T-phenyl type).

The term “% by mole based on an Si atomic molar number” as used herein refers to a percentage of the number of moles of Si atoms contained in a specific structural unit with respect to the total number of moles of Si atoms contained in all of the structural units constituting the siloxane binder.

The molar amount of a siloxane unit in the siloxane binder may be measured by the combination of Si-NMR, ¹H-NMR, ¹³C-NMR, IR, TOF-MS, elementary analysis, measurement of ash, and the like. For example, in order to measure the molar amount of a siloxane unit having a phenyl group, an Si-NMR analysis is performed on the entire siloxane binder, followed by an analysis of the phenyl-bound Si peak area and the phenyl-unbound Si peak area. The molar amount can then be computed from the peak area ratio between them.

The photosensitive resin composition of the present invention may comprise the siloxane binder in an amount of 50 to 95% by weight or 60 to 90% by weight, based on the total weight of the solids content of the composition, exclusive of solvents. If the content of the siloxane binder is within the above content range, it is possible to maintain the developability of the composition at a suitable level, thereby producing a cured film that is excellent in the film retention and the pattern resolution.

In addition, the photosensitive resin composition of the present invention may comprise the siloxane copolymer (A) and the siloxane binder (E) at a weight ratio of 1:19 to 99 or 1:28 to 39. Within the above range, it is possible to attain a low edge angle of the pattern while maintaining excellent film retention rate and sensitivity, thereby further enhancing the resolution.

Meanwhile, the present invention may use a mixture of two or more siloxane binders that have different dissolution rates in an aqueous solution of tetramethylammonium hydroxide (TMAH) as the siloxane binder. If a mixture of two or more siloxane binders as described above is used as the siloxane binder, it is possible to improve both of the sensitivity and the chemical resistance of the resin composition.

Specifically, the siloxane binder is a mixture of two or more siloxane binders that have different dissolution rates in an aqueous solution of TMAH, and the siloxane binder mixture comprises (1) a first siloxane binder that, when pre-baked, has a dissolution rate of 400 to 2,000 Å/sec in an aqueous solution of 2.38% by weight of TMAH; and (2) a second siloxane binder that, when pre-baked, has a dissolution rate of 1,900 to 8,000 Å/sec in an aqueous solution of 1.5% by weight of TMAH.

The dissolution rate of a single siloxane binder and a mixture thereof in an aqueous solution of TMAH may be measured as follows. A siloxane binder sample is added to propylene glycol monomethyl ether acetate (PGMEA, solvent) such that the solids content is 17% by weight and dissolved with stirring at room temperature for 1 hour to prepare a siloxane binder solution. Thereafter, 3 cc of the siloxane binder solution thus prepared is dropped onto a central area of a silicon wafer having a diameter of 6 inches and a thickness of 525 μm using a pipette in a clean room in an atmosphere of a temperature of 23.0±0.5° C. and a humidity of 50±5.0%, which is spin-coated such that the thickness is 1.2±0.1 μm. Thereafter, the wafer is heated on a hot plate at 105° C. for 90 seconds to remove the solvent, and the thickness of the coated film is measured with a spectroscopic ellipsometer (Woollam). Then, the dissolution rate is calculated by measuring the thickness of the cured film on the silicon wafer with respect to the dissolution time using a thin film analyzer (TFA-11CT, Shinyoung Corporation) with an aqueous solution of 2.38% by weight of TMAH or an aqueous solution of 1.5% by weight of TMAH.

The siloxane binder may comprise 60 to 100% by weight, 60 to 99% by weight, or 80 to 99% by weight, of the first siloxane binder based on the total weight of the siloxane binder. If the content of the first siloxane binder is within the above content range, it is possible to maintain the developability of the composition at a suitable level, thereby producing a cured film that is excellent in the film retention rate and the pattern resolution.

The siloxane binder may comprise 0 to 40% by weight, 1 to 40% by weight, or 1 to 20% by weight, of the second siloxane binder based on the total weight of the siloxane binder. If the content of the second siloxane binder is within the above content range, it is possible to maintain the developability of the composition at a suitable level, thereby producing a cured film that is excellent in the film retention and the pattern resolution.

(F) Photopolymerizable Compound Containing a Double Bond

The photopolymerizable compound employed in the present invention is a compound that has a double bond and is polymerizable by the action of a photopolymerization initiator.

Specifically, it may be a monofunctional or polyfunctional ester compound having at least one ethylenically unsaturated double bond. In particular, it may be a polyfunctional compound having at least two functional groups from the viewpoint of chemical resistance.

The photopolymerizable compound containing a double bond may be selected from the group consisting of ethylene glycol di(meth)acrylate, propylene glycol di(meth)acrylate, diethylene glycol di(meth)acrylate, triethylene glycol di(meth)acrylate, 1,6-hexanediol di(meth)acrylate, polyethylene glycol di(meth)acrylate, polypropylene glycol di(meth)acrylate, glycerin tri(meth)acrylate, trimethylolpropane tri(meth)acrylate, pentaerythritol tri(meth)acrylate, a monoester of pentaerythritol tri(meth)acrylate and succinic acid, pentaerythritol tetra(meth)acrylate, dipentaerythritol penta(meth)acrylate, dipentaerythritol hexa(meth)acrylate, a monoester of dipentaerythritol penta(meth)acrylate and succinic acid, a caprolactone-modified dipentaerythritol hexa(meth)acrylate, pentaerythritol triacrylate-hexamethylene diisocyanate (a reaction product of pentaerythritol triacrylate and hexamethylene diisocyanate), tripentaerythritol hepta(meth)acrylate, tripentaerythritol octa(meth)acrylate, bisphenol A epoxyacrylate, and ethylene glycol monomethyl ether acrylate, and a mixture thereof, but it is not limited thereto.

Examples of the photopolymerizable compound commercially available may include (i) monofunctional (meth)acrylate such as Aronix M-101, M-111, and M-114 manufactured by Toagosei Co., Ltd., KAYARAD T4-110S and T4-120S manufactured by Nippon Kayaku Co., Ltd., and V-158 and V-2311 manufactured by Osaka Yuki Kayaku Kogyo Co., Ltd.; (ii) bifunctional (meth)acrylate such as Aronix M-210, M-240, and M-6200 manufactured by Toagosei Co., Ltd., KAYARAD HDDA, HX-220, and R-604 manufactured by Nippon Kayaku Co., Ltd., and V-260, V-312, and V-335 HP manufactured by Osaka Yuki Kayaku Kogyo Co., Ltd.; and (iii) tri- and higher functional (meth)acrylate such as Aronix M-309, M-400, M-403, M-405, M-450, M-7100, M-8030, M-8060, and TO-1382 manufactured by Toagosei Co., Ltd., KAYARAD TMPTA, DPHA, DPHA-40H, DPCA-20, DPCA-30, DPCA-60, and DPCA-120 manufactured by Nippon Kayaku Co., Ltd., and V-295, V-300, V-360, V-GPT, V-3PA, V-400, and V-802 manufactured by Osaka Yuki Kayaku Kogyo Co., Ltd.

The photopolymerizable compound may be employed in an amount of 1 to 50 parts by weight, 2 to 50 parts by weight, or 2 to 20 parts by weight, based on 100 parts by weight of the siloxane binder (E) on the basis of the solids content. Within the above range, it is excellent in developability and has adequate flowability during hard-bake (post-bake) (i.e., flow takes place properly), so that a pattern having a desired taper angle can be formed. If it is used in an amount smaller than the above range, the flowability is not sufficient, whereby a low taper angle is not formed. If it is excessively used, there may arise a problem that the flow of the composition is caused during hard-bake (i.e., the flowability is increased), whereby the resolution of a pattern is deteriorated.

(G) Surfactant

The photosensitive resin composition of the present invention may further comprise a surfactant to enhance its coatability, if desired.

The kind of the surfactant is not particularly limited, but examples thereof include fluorine-based surfactants, silicone-based surfactants, non-ionic surfactants, and the like.

Specific examples of the surfactant include fluorine- and silicon-based surfactants such as FZ-2122 supplied by Dow Corning Toray Co., Ltd., BM-1000 and BM-1100 supplied by BM CHEMIE Co., Ltd., Megapack F-142 D, F-172, F-173, and F-183 supplied by Dai Nippon Ink Chemical Kogyo Co., Ltd., Florad FC-135, FC-170 C, FC-430, and FC-431 supplied by Sumitomo 3M Ltd., Sufron S-112, S-113, 5-131, S-141, 5-145, 5-382, SC-101, SC-102, SC-103, SC-104, SC-105, and SC-106 supplied by Asahi Glass Co., Ltd., Eftop EF301, EF303, and EF352 supplied by Shinakida Kasei Co., Ltd., SH-28 PA, SH-190, SH-193, SZ-6032, SF-8428, DC-57, and DC-190 supplied by Toray Silicon Co., Ltd.; non-ionic surfactants such as polyoxyethylene alkyl ethers including polyoxyethylene lauryl ether, polyoxyethylene stearyl ether, polyoxyethylene oleyl ether, and the like; polyoxyethylene aryl ethers including polyoxyethylene octylphenyl ether, polyoxyethylene nonylphenyl ether, and the like; and polyoxyethylene dialkyl esters including polyoxyethylene dilaurate, polyoxyethylene distearate, and the like; and organosiloxane polymer KP341 (manufactured by Shin-Etsu Chemical Co., Ltd.), (meth)acrylate-based copolymer Polyflow Nos. 57 and 95 (manufactured by Kyoei Yuji Chemical Co., Ltd.), and the like. They may be used alone or in combination of two or more thereof.

The photosensitive resin composition of the present invention may comprise the surfactant in an amount of 0.5 to 20% by weight or 4 to 12% by weight, based on the total weight of the solids content of the composition, exclusive of solvents. Within the above content range, the coating and leveling characteristics of the composition may be good.

(H) Silane Compound

The photosensitive resin composition of the present invention may further comprise a silane compound, to thereby improve the chemical resistance in the treatment of a subsequent process by reducing the content of highly reactive silanol groups (Si—OH) in the siloxane polymer, in association with the epoxy compound.

The silane compound may be a compound represented by the following Formula 4.

(R₇)_{q}Si(OR₈)_{4-q} [Formula 4]

In Formula 4, R₇ is each independently C₁₋₁₂ alkyl, C₂₋₁₀ alkenyl, C₆₋₁₅ aryl, 3- to 12-membered heteroalkyl, 4- to 10-membered heteroalkenyl, or 6- to 15-membered heteroaryl, and the heteroalkyl, the heteroalkenyl, and the heteroaryl groups each independently contain at least one identical or different heteroatom selected from the group consisting of N, O and S; R₈ is each independently hydrogen, C₁₋₅ alkyl, C₂₋₆ acyl, or C₆₋₁₅ aryl; and q is an integer of 0 to 3.

It may be a tetrafunctional silane compound where q is 0, a trifunctional silane compound where q is 1, a difunctional silane compound where q is 2, or a monofunctional silane compound where q is 3.

Particular examples of the silane compound may include, e.g., as the tetrafunctional silane compound, tetraacetoxysilane, tetramethoxysilane, tetraethoxysilane, tetrabutoxysilane, tetraphenoxysilane, tetrabenzyloxysilane, and tetrapropoxysilane; as the trifunctional silane compound, methyltrimethoxysilane, methyltriethoxysilane, methyltriisopropoxysilane, methyltributoxysilane, ethyltrimethoxysilane, ethyltriethoxysilane, ethyltriisopropoxysilane, ethyltributoxysilane, butyltrimethoxysilane, pentafluorophenyltrimethoxysilane, phenyltrimethoxysilane, phenyltriethoxysilane, d³-methyltrimethoxysilane, nonafluorobutylethyltrimethoxysilane, trifluoromethyltrimethoxysilane, n-propyltrimethoxysilane, n-propyltriethoxysilane, n-butyltriethoxysilane, n-hexyltrimethoxysilane, n-hexyltriethoxysilane, decyltrimethoxysilane, vinyltrimethoxysilane, vinyltriethoxysilane, 3-methacryloxypropyltrimethoxysilane, 3-methacryloxypropyltriethoxysilane, 3-acryloxypropyltrimethoxysilane, 3-acryloxypropyltriethoxysilane, p-hydroxyphenyltrimethoxysilane, 1-(p-hydroxyphenyl)ethyltrimethoxysilane, 2-(p-hydroxyphenyl)ethyltrimethoxysilane, 4-hydroxy-5-(p-hydroxyphenylcarbonyloxy)pentyltrimethoxysilane, trifluoromethyltriethoxysilane, 3,3,3-trifluoropropyltrimethoxysilane, 3-aminopropyltrimethoxysilane, 3-aminopropyltriethoxysilane, 3-glycidoxypropyltrimethoxvsilane, 3-glycidoxypropyltriethoxysilane, 2-(3,4-epoxycyclohexyl)ethyltrimethoxvsilane, 2-(3,4-epoxycyclohexyl)ethyltriethoxysilane, [(3-ethyl-3-oxetanyl)methoxy]propyltrimethoxysilane, [(3-ethyl-3-oxetanyl)methoxy]propyltriethoxysilane, 3-mercaptopropyltrimethoxysilane, and 3-trimethoxysilylpropylsuccinic acid; as the difunctional silane compound, dimethyldiacetoxysilane, dimethyldimethoxysilane, diphenyldimethoxysilane, diphenyldiethoxysilane, diphenyldiphenoxysilane, dibutyldimethoxysilane, dimethyldiethoxysilane, (3-glycidoxypropyl)methyldimethoxysilane, (3-glycidoxypropyl)methyldiethoxysilane, 3-(2-aminoethylamino)propyldimethoxymethylsilane, 3-aminopropyldiethoxymethylsilane, 3-chloropropyldimethoxymethylsilane, 3-mercaptopropyldimethoxymethylsilane, cyclohexyldimethoxymethylsilane, diethoxymethylvinylsilane, dimethoxymethylvinylsilane, and dimethoxydi-p-tolylsilane; and as the monofunctional silane compound, trimethylmethoxysilane, tributylmethoxysilane, trimethylethoxysilane, (3-glycidoxypropyl)dimethylmethoxysilane, and (3-glycidoxypropyl)dimethylethoxysilane.

Preferred among the tetrafunctional silane compounds are tetramethoxysilane, tetraethoxysilane, and tetrabutoxysilane; preferred among the trifunctional silane compoundsaremethyltrimethoxysilane, methyltriethoxysilane, methyltriisopropoxysilane, methyltributoxysilane, phenyltrimethoxysilane, ethyltrimethoxysilane, ethyltriethoxysilane, ethyltriisopropoxysilane, ethyltributoxysilane, butyltrimethoxysilane, 3-glycidoxypropyltrimethoxysilane, 3-glycidoxypropyltriethoxysilane, 2-(3,4-epoxycyclohexyl)ethyltrimethoxysilane, and 2-(3,4-epoxycyclohexyl)ethyltriethoxysilane; preferred among the difunctional silane compounds are dimethyldimethoxysilane, diphenyldimethoxysilane, diphenyldiethoxysilane, diphenyldiphenoxysilane, dibutyldimethoxysilane, and dimethyldiethoxysilane. These silane compounds may be used alone or in combination of two or more thereof.

Specifically, the silane compound may be a tetrafunctional silane compound (Q type silane compound) where q is 0 or a trifunctional silane compound (T type silane compound) where q is 1.

The silane compound may be employed in an amount ranging from 0 to 20 parts by weight, 1 to 15 parts by weight, or 4 to 12 parts by weight, based on 100 parts by weight of the siloxane binder (E) on the basis of the solids content. If the content of the silane compound is within the above range, the chemical resistance of a cured film to be formed may be further enhanced.

In addition, the photosensitive resin composition of the present invention may further comprise other additives as long as the physical properties of the photosensitive resin composition are not adversely affected.

The photosensitive resin composition according to the present invention may be used as a positive-type photosensitive resin composition. Further, the present invention provides a cured film formed from the positive-type photosensitive resin composition.

The cured film may be formed by a method known in the art, for example, a method in which the photosensitive resin composition is coated on a substrate and then cured.

More specifically, in the curing step, the photosensitive resin composition coated on a substrate may be subjected to pre-bake at a temperature of, for example, 60° C. to 130° C. to remove solvents; then exposed to light using a photomask having a desired pattern; and subjected to development using a developer, for example, a tetramethylammonium hydroxide (TMAH) solution to form a pattern on the coating layer. Thereafter, the patterned coating layer, if necessary, is subjected to hard-bake, for example, at a temperature of 150° C. to 300° C. for 10 minutes to 5 hours to prepare a desired cured film. The exposure to light may be carried out at an exposure dose of 10 mJ/cm² to 200 mJ/cm² based on a wavelength of 365 nm in a wavelength band of 200 nm to 500 nm. According to the process of the present invention, it is possible to easily form a desired pattern from the viewpoint of the process.

The coating of the photosensitive resin composition onto a substrate may be carried out by a spin coating method, a slit coating method, a roll coating method, a screen printing method, an applicator method, or the like, in a desired thickness of, e.g., 2 μm to 25 μm. In addition, as a light source used for the exposure (irradiation), a low-pressure mercury lamp, a high-pressure mercury lamp, an extra high-pressure mercury lamp, a metal halide lamp, an argon gas laser, or the like may be used. X-ray, electronic ray, or the like may also be used, if desired.

Meanwhile, the photosensitive resin composition may be subjected to photobleaching at an energy of 300 mJ/cm² to 2,000 m/cm² or 500 mJ/cm² to 1,500 mJ/cm² after the exposure to light and development to obtain a more transparent cured film. Specifically, the composition may be coated on a substrate and subjected to the exposure to light and development steps, followed by photobleaching and hard-bake thereof to form a cured film. The photobleaching step removes the bonds between the siloxane binder and/or the siloxane copolymer as the major components of the positive-type photosensitive resin composition and the 1,2-quinonediazide compound, thereby forming a transparent cured film. If the hard-bake is carried out without the photobleaching step, a reddish cured film is obtained, so that the transmittance in the region of, for example, 400 to 600 nm may be deteriorated.

The photosensitive resin composition of the present invention is capable of providing a cured film having excellent physical properties in terms of sensitivity, film retention rate, resolution, and the like upon development and upon hard-bake. In particular, since the cured film formed from the composition has excellent resolution due to its low edge angle of the pattern, it can be advantageously used as a pixel defining layer of an organic light emitting device and a quantum dot light emitting device.

As described above, the positive-type photosensitive resin composition according to the present invention comprises a siloxane copolymer having specific structural units. Thus, a cured film formed from the composition may achieve a low edge angle of the pattern, thereby enhancing the resolution without deteriorating such physical properties as film retention rate and sensitivity.

### EMBODIMENTS FOR CARRYING OUT THE INVENTION

Hereinafter, the present invention will be described in more detail with reference to the following examples. However, these examples are provided to illustrate the present invention, and the scope of the present invention is not limited thereto only.

In the following preparation examples, the weight average molecular weight is determined by gel permeation chromatography (GPC, eluent: tetrahydrofuran) referenced to a polystyrene standard.

### Example

### Preparation Example 1

A reactor equipped with a reflux condenser was charged with 29% by weight of phenyltrimethoxysilane (PTMS), 10% by weight of methyltrimethoxysilane (MTMS), 18% by weight of diphenyldimethoxysilane (DPDMS), 15% by weight of distilled water, and 28% by weight of propylene glycol monomethyl ether acetate (PGMEA) as a solvent, followed by refluxing and vigorously stirring the mixture for 4 hours in the presence of 0.5% by weight of a sulfuric acid catalyst. Then, the mixture was cooled and diluted with PGMEA such that the solids content was 40%. As a result, a siloxane copolymer (A-1) having a molecular weight of 500 to 1,500 Da was prepared.

### Preparation Examples 2 and 3

Siloxane copolymers A-2 and A-3 were prepared in the same manner as in Preparation Example 1, except that the kinds and/or contents of the substances were changed as shown in Table 1 below.

### Preparation Example 4

The respective components were mixed with different types and/or contents as shown in Table 1 below, which mixture was then stirred under reflux for 5 hours in the presence of an oxalic acid catalyst. Then, the mixture was cooled and diluted with PGMEA such that the solids content was 45%. As a result, a siloxane copolymer A-4 having a molecular weight of 4,000 to 6,000 Da was prepared.

TABLE 1

| | (Wt. %) | | | | | | | |
|---|---|---|---|---|---|---|---|---|
| | | | | Diphenyldieth- | | Distilled | | Molecular |
| | PTMS | MTMS | DPDMS | oxysilane | TES | water | PGMEA | weight(Da) |
| A-1 | 29 | 10 | 18 | — | — | 15 | 28 | 500 to 1,500 |
| A-2 | 22 | 8 | 27 | — | — | 13 | 30 | 500 to 1,500 |
| A-3 | 13 | 5 | 41 | — | — | 11 | 30 | 500 to 1,500 |
| A-4 | 25 | 10 | — | 9 | 15 | 20 | 20 | 4,000 to 6,000 |

TES: tetraethoxysilane

### Preparation Example 5

A reactor equipped with a reflux condenser was charged with 40% by weight of phenyltrimethoxysilane, 15% by weight of methyltrimethoxysilane, 20% by weight of tetraethoxysilane (TES), 20% by weight of distilled water, and 5% by weight of propylene glycol monomethyl ether acetate (PGMEA), followed by refluxing and vigorously stirring the mixture for 7 hours in the presence of 0.1% by weight of an oxalic acid catalyst. Then, the mixture was cooled and diluted with PGMEA such that the solids content was 40%. As a result, a siloxane binder (E-1) having a molecular weight of 5,000 to 8,000 Da was prepared.

### Preparation Example 6

A siloxane binder E-2 was prepared in the same manner as in Preparation Example 1, except that the kinds and/or contents of the substances were changed as shown in Table 2 below and the mixture was refluxed and vigorously stirred for 8 hours. The dissolution rate of the siloxane binder in an aqueous solution of TMAH was measured by the method described in the present specification. As a result, the dissolution rate upon pre-bake in an aqueous solution of 2.38% by weight of TMAH was 1,959.5 Å/sec.

### Preparation Example 7

A siloxane binder E-3 was prepared in the same manner as in Preparation Example 1, except that the kinds and/or contents of the substances were changed as shown in Table 2 below. The dissolution rate of the siloxane binder in an aqueous solution of TMAH was measured by the method described in the present specification. As a result, the dissolution rate upon pre-bake in an aqueous solution of 2.38% by weight of TMAH was 7,000 Å/sec.

### Preparation Example 8

A 500-ml, round-bottomed flask equipped with a refluxing condenser and a stirrer was charged with 100 g of a monomer mixture composed of 22% by mole of methacrylic acid (MAA), 20% by mole of styrene (Sty), 15% by mole of (3,4-epoxycyclohexyl)methyl methacrylate (CH-epoxy), 24% by mole of methyl methacrylate (MMA), 14% by mole of methacrylate (MA), and 5% by mole of cyclohexyl methacrylate (CHMA), along with 300 g of PGMEA as a solvent and 2 g of 2,2′-azobis(2,4-dimethylvaleronitrile) as a radical polymerization initiator. The mixture was then heated to 70° C. and stirred for 5 hours to obtain an acrylate-based binder (E-4) having a solids content of 28% by weight. The copolymer thus prepared had a weight average molecular weight of 6,600 Da when measured by gel permeation chromatography with a polystyrene reference.

### Preparation Example 9

An acrylate-based binder E-5 was prepared in the same manner as in Preparation Example 4, except that the kinds and/or contents of the substances were changed as shown in Table 3 below.

TABLE 2

| | (Wt. %) | | | | | |
|---|---|---|---|---|---|---|
| | | | | Distilled | | Molecular |
| | PTMS | MTMS | TES | water | PGMEA | weight (Da) |
| E-1 | 40 | 15 | 20 | 20 | 5 | 5,000~8,000 |
| E-2 | 20 | 30 | 20 | 15 | 15 | 10,000~13,000 |
| E-3 | 20 | 30 | 20 | 15 | 15 | 11,000~14,000 |

TABLE 3

| | (Mole %) | | | | | | | |
|---|---|---|---|---|---|---|---|---|
| | | | CH- | | | | Glycidyl | Molecular |
| | MAA | Sty | epoxy | MMA | MA | CHMA | methacrylate | weight (Da) |
| E-4 | 22 | 20 | 15 | 24 | 14 | 5 | 0 | 6,600 |
| E-5 | 21 | 20 | 0 | 36 | 8 | 0 | 15 | 7,600 |

Examples and Comparative Examples: Preparation of Photosensitive Resin Compositions

The photosensitive resin compositions of the following Examples and Comparative Examples were each prepared using the compounds prepared in the above Preparation Examples.

The components used in the following Examples and Comparative Examples are as follows.

TABLE 4

| | | | Solids content | |
|---|---|---|---|---|
| Component | | | (% by weight) | Manufacturer |
| Siloxane copolymer (A) | | Preparation Example 1 | 40 | — |
| | | Preparation Example 2 | 40 | — |
| | | Preparation Example 3 | 40 | — |
| | | Preparation Example 4 | 45 | — |
| Photoactive compound (B) | B-1 | TPA-517 | 100 | Miwon |
| | B-2 | THD-523 | 100 | Miwon |
| | B-3 | TPA-523 | 100 | Miwon |
| Solvent (C) | C-1 | Propylene glycol monomethyl | — | Chemtronix |
| | | ether acetate (PGMEA) | | |
| | C-2 | γ-butyrolactone | — | BASF |
| Epoxy compound (D) | D-1 | GHP03HP | 20 | Miwon |
| | D-2 | GHP24HP | 20 | Miwon |
| Siloxane binder (E) | E-1 | Preparation Example 5 | 40 | — |
| | E-2 | Preparation Example 6 | 30 | — |
| | E-3 | Preparation Example 7 | 30 | — |
| Acrylate-based binder | E-4 | Preparation Example 8 | 28 | — |
| | E-5 | Preparation Example 9 | 32 | — |

| | | | |
|---|---|---|---|
| Photopolymerizable compound (F) | Dipentaerythritol hexaacrylate | 100 | Nippon |
| | | | Kayaku |
| Surfactant (G) | Silicone-based leveling | 100 | Dow Corning |
| | surfactant, FZ-2122 | | Toray |
| Silane compound (H) | OFS-6124 | 100 | Xiameter |
| Adhesion Aid (I) | Sila-Ace XS1075 | 100 | JNC |

### Example 1

100 parts by weight of a mixture consisting of 3.4% by weight of the siloxane copolymer (A-1) of Preparation Example 1, 32.9% by weight of the siloxane binder (E-1) of Preparation Example 5, 39.1% by weight of the siloxane binder (E-2) of Preparation Example 6, and 24.6% by weight of the siloxane binder (E-3) of Preparation Example 7 was uniformly mixed with 13.7 parts by weight of a 1,2-quinonediazide-based compound (B-1), 14.3 parts by weight of an epoxy compound (D-1), 0.3 parts by weight of a surfactant (G), and 5.7 parts by weight of a silane compound (H). Here, the respective contents are those based on the solids content exclusive of solvents. The mixture was dissolved in a mixed solvent of (C-1) PGMEA and (C-2) GBL (PGMEA:GBL=93:7) such that the solids content of the mixture was 17% by weight. The resultant was stirred for 1 to 2 hours and filtered through a membrane filter having a pore size of 0.2 μm to obtain a liquid-phase photosensitive resin composition solution having a solids content of 17% by weight.

### Examples 2 to 6 and Comparative Examples 1 to 3

Photosensitive resin compositions were each prepared in the same manner as in Example 1, except that the kinds and/or the contents of the respective components were changed as shown in Table 5 below.

TABLE 5

| | Siloxane | | | | Siloxane | | | Acrylate- | |
|---|---|---|---|---|---|---|---|---|---|
| | copolymer (A) | | | | binder (E) | | | based binder | |
| | A-1 | A-2 | A-3 | A-4 | E-1 | E-2 | E-3 | E-4 | E-5 |
| Ex. 1 | 3.4 | — | — | — | 32.9 | 39.1 | 24.6 | — | — |
| Ex. 2 | — | 3.4 | — | — | 32.9 | 39.1 | 24.6 | — | — |
| Ex. 3 | — | — | 3.4 | — | 32.9 | 39.1 | 24.6 | — | — |
| Ex. 4 | 3.4 | — | — | — | 32.9 | 39.1 | 24.6 | — | — |
| Ex. 5 | — | 3.4 | — | — | 32.9 | 39.1 | 24.6 | — | — |
| Ex. 6 | — | — | 3.4 | — | 32.9 | 39.1 | 24.6 | — | — |
| C. Ex. 1 | — | — | — | — | 32.9 | 39.1 | 24.6 | — | — |
| C. Ex. 2 | — | — | — | 3.4 | 32.9 | 39.1 | 24.6 | — | — |
| C. Ex. 3 | — | — | — | — | — | — | — | 51.5 | 48.5 |

TABLE 6

| | Photoactive | | | Epoxy | | | | Photopolymer- | | | |
|---|---|---|---|---|---|---|---|---|---|---|---|
| | compound (B) | | | compound (D) | | Solvent (C) | | izable | Surfactant | Silane | Adhesion |
| | B-1 | B-2 | B-3 | D-1 | D-2 | C-1 | C-2 | compound (F) | (G) | compound (H) | aid (I) |
| Ex. 1 | 13.7 | — | — | 14.3 | — | 93 | 7 | — | 0.3 | 5.7 | — |
| Ex. 2 | 13.7 | — | — | 14.3 | — | 93 | 7 | — | 0.3 | 5.7 | — |
| Ex. 3 | 13.7 | — | — | 14.3 | — | 93 | 7 | — | 0.3 | 5.7 | — |
| Ex. 4 | 13.7 | — | — | 14.3 | — | 93 | 7 | 4 | 0.3 | 5.7 | — |
| Ex. 5 | 13.7 | — | — | 14.3 | — | 93 | 7 | 4 | 0.3 | 5.7 | — |
| Ex. 6 | 13.7 | — | — | 14.3 | — | 93 | 7 | 4 | 0.3 | 5.7 | — |
| C. Ex. 1 | 13.7 | — | — | 14.3 | — | 93 | 7 | — | 0.3 | 5.7 | — |
| C. Ex. 2 | 13.7 | — | — | 14.3 | — | 93 | 7 | — | 0.3 | 5.7 | — |
| C. Ex. 3 | — | 8.4 | 7.1 | — | 3.1 | 93 | 7 | — | 0.2 | — | 0.4 |

### Evaluation Example

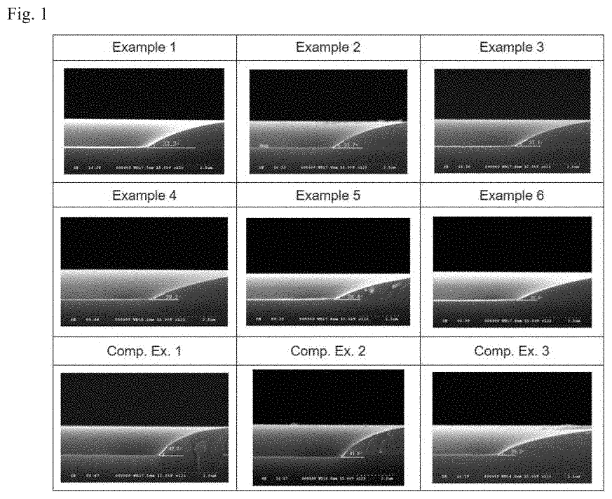

Cured films were each prepared from the photosensitive resin compositions obtained in Examples 1 to 6 and Comparative Examples 1 to 3. The film retention rate, resolution, and edge angle of the pattern thereof were evaluated. The results are shown in Table 7 below and FIG. 1.

### Evaluation Example 1: Evaluation of Film Retention Rate

The compositions prepared in the Examples and the Comparative Examples were each coated onto a glass substrate by spin coating. The coated substrate was then pre-baked on a hot plate kept at 105° C. for 90 seconds to form a dry film. Thereafter, it was developed with an aqueous solution diluted to 2.38% by weight of TMAH through puddle nozzles at 23° C. for 60 seconds. It was then exposed to light at an exposure dose of 200 mJ/cm² based on a wavelength of 365 nm for a certain time period using an aligner (model name: MA6) that emits light having a wavelength of 200 nm to 450 nm (i.e., photobleaching). The exposed film was hard-baked in a convection oven at 230° C. for 30 minutes to prepare a cured film having a thickness of 2 μm.

The film retention rate (%) was obtained by calculating the ratio in a percent of the thickness of the film upon the hard-bake to that of the film upon the pre-bake by using a film thickness measuring instrument (SNU Precision). The larger the numerical value, the better the film retention rate. If the film retention rate was about 80% or more, it was evaluated to be excellent.

Film retention rate (%)=(film thickness upon hard-bake/film thickness upon pre-bake)×100

### Evaluation Example 2: Evaluation of Resolution

A dry film was obtained in the same manner as in Evaluation Example 1. A mask having a pattern of square holes and lines in a size ranging from 1 μm to 20 μm, wherein the same pattern array is made in a gray scale, was placed on the dry film. Thereafter, the film was exposed to light at an exposure dose of 0 to 70 mJ/cm² based on a wavelength of 365 nm for a certain time period using an aligner (model name: MA6) that emits light having a wavelength of 200 nm to 450 nm. Thereafter, the dry film was developed with an aqueous solution of 2.38% by weight of TMAH through puddle nozzles at 23° C. for 60 seconds. Then, the film was exposed to light at an exposure dose of 200 mJ/cm² based on a wavelength of 365 nm for a certain time period using an aligner (model name: MA6) that emits light having a wavelength of 200 nm to 450 nm. The exposed film thus obtained was heated in a convection oven at 230° C. for 30 minutes to prepare a cured film having a thickness of 2.0 μm.

The minimum size of the pattern of the cured film in which no residual film remains was measured. The smaller the pattern size, the better the resolution.

### Evaluation Example 3: Evaluation of the Edge of Pattern—Measurement of Taper Angle

A cured film was obtained in the same manner as in Evaluation Example 2. A transversal cross-sectional view was taken with a scanning electron microscope (5-4300, manufacturer: Hitachi) for holes of 10 μm in the pattern of the cured film. The angle between the edge of the pattern and the substrate side at the interface between the edge of the pattern and the substrate was measured using a micro-optical microscope (STM6-LM, manufacturer: OLYMPUS). It was evaluated as excellent when the angle was 40° or less.

TABLE 7

| | Film retention rate | Resolution | Taper angle |
|---|---|---|---|
| | (%) | (μm) | (°) |
| Ex. 1 | 93 | 4 | 33.3 |
| Ex. 2 | 93 | 4 | 31.7 |
| Ex. 3 | 93 | 4 | 31.1 |
| Ex. 4 | 92 | 4 | 29.2 |
| Ex. 5 | 88 | 4 | 24.4 |
| Ex. 6 | 90 | 4 | 22.6 |
| C. Ex. 1 | 94 | 4 | 47.7 |
| C. Ex. 2 | 95 | 4 | 41.8 |
| C. Ex. 3 | 55 | 6 | 25.2 |

As shown in Table 7 and FIG. 1, all of the cured films prepared from the compositions of the Examples, falling within the scope of the present invention, were excellent in film retention rate. All of the hole patterns were found to be 4 μm or less, whereby the resolution was excellent. In addition, all of the cured films prepared from the compositions of the Examples had a taper angle of 40° or less. In contrast, the cured films prepared from the compositions of Comparative Examples 1 to 3 were inferior to those of the Examples in terms of film residual rate, resolution, and/or pattern edge.

1. A positive-type photosensitive resin composition, which comprises:
(A) a siloxane copolymer comprising a structural unit represented by the following Formula 1 and a structural unit represented by the following Formula 2;
(B) a photoactive compound; and
(C) a solvent: 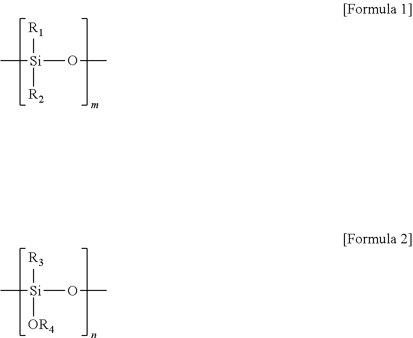
in Formulae 1 and 2,
R₁, R₂, and R₃ are each independently C₁₋₁₂ alkyl, C₂₋₁₀ alkenyl, C₆₋₁₅ aryl, 3- to 12-membered heteroalkyl, 4- to 10-membered heteroalkenyl, or 6- to 15-membered heteroaryl, at least one of R₁, R₂, and R₃ is C₆₋₁₅ aryl, and the heteroalkyl, the heteroalkenyl, and the heteroaryl groups each independently contain at least one identical or different heteroatom selected from the group consisting of N, O and S;
R₄ is each independently hydrogen, C₁₋₆ alkyl, C₂₋₆ acyl, or C₆₋₁₅ aryl; and
m and n are mole fractions of the structural units, which satisfy 0.25≤m≤0.63, 0.37≤n≤0.75, and m+n=1.

2. The positive-type photosensitive resin composition of claim 1, wherein the siloxane copolymer (A) comprises a phenyl group and comprises the phenyl group at a molar ratio of 1 to 1.5 per 1 mole of Si atom.

3. The positive-type photosensitive resin composition of claim 1, wherein the siloxane copolymer (A) has a weight average molecular weight of 500 to 2,000 Da and an acid value of 5 to 15 mg KOH/g.

4. The positive-type photosensitive resin composition of claim 1, which comprises the siloxane copolymer (A) in an amount of 0.1 to 10% by weight based on the total weight of the photosensitive resin composition exclusive of the solvent (C).

5. The positive-type photosensitive resin composition of claim 1, which comprises a siloxane binder (E) comprising a structural unit derived from a silane compound represented by the following Formula 3:
(R₅)ₚSi(OR₆)₄₋ₚ [Formula 3]
in Formula 3,
R₅ is each independently C₁₋₁₂ alkyl, C₂₋₁₀ alkenyl, C₆₋₁₅ aryl, 3- to 12-membered heteroalkyl, 4- to 10-membered heteroalkenyl, or 6- to 15-membered heteroaryl, and the heteroalkyl, the heteroalkenyl, and the heteroaryl groups each independently contain at least one identical or different heteroatom selected from the group consisting of N, O, and S;
R₆ is each independently hydrogen, C₁₋₅ alkyl, C₂₋₆ acyl, or C₆₋₁₅ aryl; and
p is an integer of 0 to 3.

6. The positive-type photosensitive resin composition of claim 1, wherein the photoactive compound (B) comprises at least one selected from the group consisting of 1,2-quinonediazide 4-sulfonic acid ester, 1,2-quinonediazide 5-sulfonic acid ester, and 1,2-quinonediazide 6-sulfonic acid ester.

7. The positive-type photosensitive resin composition of claim 1, which further comprises a photopolymerizable compound (F) containing a double bond.

8. A cured film prepared from the photosensitive resin composition of claim 1.

9. The cured film of claim 8, which is a pixel defining film of an organic light-emitting device and a quantum dot light-emitting device.
